(19) United States
(12) Patent Application Publication
(10) Pub. No.: US 2025/0293596 A1
(43) Pub. Date: Sep. 18, 2025

(54) RESONANT CONVERTER FOR A CORONA GENERATOR

(71) Applicant: BOURNS, INC., Riverside, CA (US)

(72) Inventors: Alireza Namdmalan, Cork (IE); Desmond O'Brien, Skibbereen (IE); Cathal Sheehan, Douglas (IE)

(21) Appl. No.: 18/602,730

(22) Filed: Mar. 12, 2024

(51) Int. Cl. H02M 3/00; H01J 37/32; H02M 3/335

(52) U.S. Cl. CPC H02M 3/015; H01J 37/32073; H02M 3/33507

(57) ABSTRACT

A resonant converter for a corona generator. One example provides a corona generator that includes a resonant converter, a voltage multiplier, a driver circuit, a driver circuit power supply, and a controller. The voltage multiplier circuit is connected to the resonant converter is configured to amplifier a converter output voltage of the resonant converter, thereby generating a corona generator output. The driver circuit is connected to the resonant converter and is configured to provide a driver signal to the resonant converter. The driver circuit power supply is configured to provide power to the driver circuit. The controller is configured to receive voltage feedback indicative of a voltage of the corona generator output, compare the voltage feedback to a desired output voltage of the corona generator output, and transmit a command to the driver circuit power supply to adjust an amount of power provided to the driver circuit.

### BACKGROUND

Examples, instances, and aspects described herein relate to power supply systems and, in particular, control of resonant converters in corona generators.

### SUMMARY

Corona generators, or corona discharge generators, are generators that create electrical charges to ionize air. Corona generators may be used in applications such as air purification and ozone generation. Corona generators contain a power supply capable of converting an input voltage to several kilovolts of voltage between an electrode and a ground, creating a corona discharge. Common power supply topologies may include, for example, a fly-forward topology connected to a Villard voltage multiplier. While such a topology is simple to implement and requires relatively few components, the topology is often constrained by the switching frequency and the level of radiated emissions. Other topologies, such as resonant half-bridge or full-bridge converters operate at higher switching frequencies and have lower levels of radiated emissions than a fly-forward scheme. However, resonant topology often includes more components than a fly-forward scheme and is, therefore, more expensive while occupying a greater amount of space on a circuit board.

Among other things, examples, instances, and aspects described herein reduce the complexity and expense of resonant topologies in corona generators, thereby enabling implementation of resonant topologies in air purification and ozone generator applications, including such applications in automotives. Some examples provide a microprocessor-controlled resonant converter connected to a voltage multiplier capable of generating a voltage having a magnitude greater than 10 kV using a 12V vehicle battery. Additionally, the output voltage of the corona generator is controlled using a closed loop feedback control system. The output voltage may be controlled, for example, by adjusting the power applied to a driver of the resonant converter and/or by adjusting the frequency of the control signal applied to the driver of the resonant converter. Feedback on the output of the corona generator is used to adjust the power applied to the driver and the frequency of the control signal applied to the driver.

One example provides a corona generator comprising a resonant converter, a voltage multiplier circuit, a driver circuit, a driver circuit power supply, and a controller. The voltage multiplier circuit is connected to the resonant converter and is configured to amplifier a converter output voltage of the resonant converter, thereby generating a corona generator output. The driver circuit is connected to the resonant converter and is configured to provide a driver signal to the resonant converter. The driver circuit power supply is configured to provide power to the driver circuit. The controller includes an electronic processor and is connected to the driver circuit and the driver circuit power supply. The controller is configured to receive voltage feedback indicative of a voltage of the corona generator output, compare the voltage feedback to a desired output voltage of the corona generator output, and transmit a command to the driver circuit power supply to adjust an amount of power provided to the driver circuit.

Another example provides a method for controlling a corona generator, the corona generator including a resonant converter, a voltage multiplier circuit connected to the resonant converter and configured to amplify a converter output voltage of the resonant converter, thereby generating a corona generator output, a driver circuit connected to the resonant converter and configured to provide a driver signal to the resonant converter, and a driver circuit power supply configured to provide power to the driver circuit. The method includes receiving voltage feedback indicative of a voltage of the corona generator output, comparing the voltage feedback to a desired output voltage of the corona generator output, and transmitting a command to the driver circuit power supply to adjust an amount of power provided to the driver circuit.

Another example provides a non-transitory computer-readable medium storing instructions that, when executed by an electronic processor, cause the electronic processor to perform operations comprising receiving voltage feedback indicative of a voltage of a corona generator output for a corona generator, comparing the voltage feedback to a desired output voltage of the corona generator output, and transmitting a command to a driver circuit power supply to adjust an amount of power provided to a driver circuit of the corona generator.

Other features, aspects, and benefits of various examples will become apparent by consideration of the detailed description and accompanying drawings.

### BRIEF DESCRIPTION OF THE DRAWINGS

In the accompanying figures similar or the same reference numerals may be repeated to indicate corresponding or analogous elements. These figures, together with the detailed description, below are incorporated in and form part of the specification and serve to further illustrate various embodiments, examples, aspects, and features of concepts that include the claimed subject matter, and to explain various principles and advantages of those embodiments, examples, aspects, and features.

FIG. 1 illustrates a block diagram of a corona generator in accordance with some aspects;

FIG. 2 illustrates a block diagram of a controller of FIG. 1 in accordance with some aspects;

FIG. 3 illustrates a circuit diagram of a driver circuit of FIG. 1 in accordance with some aspects;

FIG. 4 illustrates a circuit diagram of a driver circuit power supply of FIG. 1 in accordance with some aspects;

FIG. 5 illustrates a circuit diagram of a voltage multiplier of FIG. 1 in accordance with some aspects;

FIG. 6 illustrates a circuit diagram of an output voltage feedback circuit of FIG. 1 in accordance with some aspects;

FIG. 7 illustrates a circuit diagram of a current feedback circuit of FIG. 1 in accordance with some aspects;

FIG. 8 illustrates a block diagram of a method for adjusting power provided to the driver circuit of FIG. 1 in accordance with some aspects;

FIG. 9 illustrates a block diagram of a method for detecting operational errors of the corona generator of FIG. 1 in accordance with some aspects;

FIG. 10 illustrates a block diagram of another method for detecting operational errors of the corona generator of FIG. 1 in accordance with some aspects; and

FIG. 11 illustrates a block diagram for adjusting a frequency provided to the driver circuit of FIG. 1 in accordance with some aspects.

Skilled artisans will appreciate that elements in the figures are illustrated for simplicity and clarity and have not necessarily been drawn to scale. For example, the dimensions of some of the elements in the figures may be exaggerated relative to other elements to help improve understanding of the examples, aspects, and features presented in this disclosure.

The system, apparatus, and method components have been represented where appropriate by conventional symbols in the drawings, showing only those specific details that are pertinent to understanding of the various embodiments, examples, aspects, and features of the present disclosure so as not to obscure the disclosure with details that will be readily apparent to those of ordinary skill in the art having the benefit of the description herein.

### DETAILED DESCRIPTION

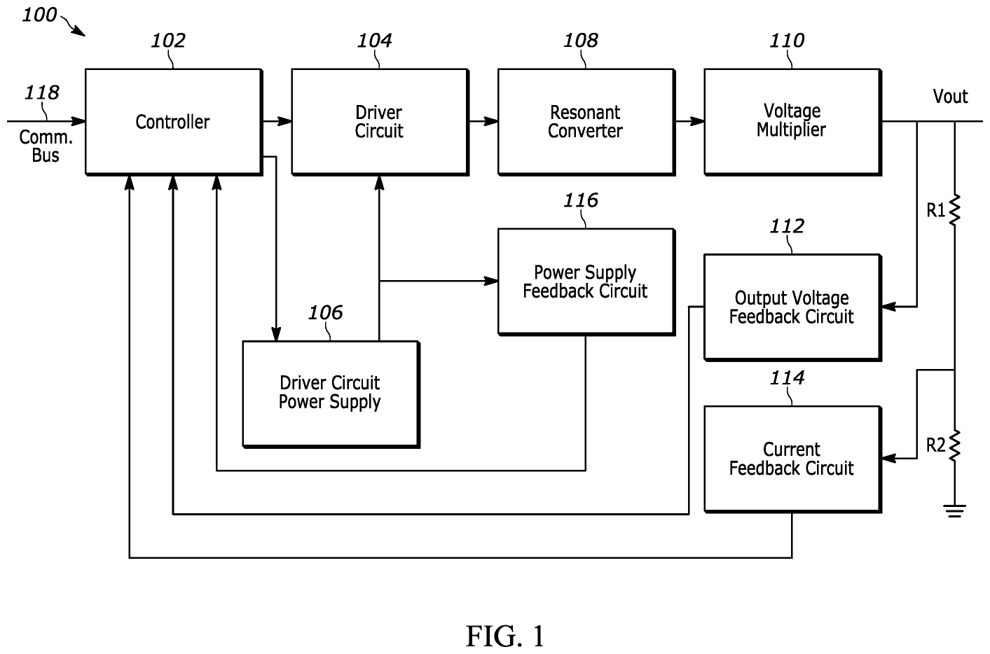

FIG. 1 illustrates a block diagram of a corona generator 100 in accordance with some aspects. The corona generator 100 includes, among other things, a controller 102, a driver circuit 104, a driver circuit power supply 106, a resonant converter 108, and a voltage multiplier 110. The controller 102 is connected to the driver circuit 104 and the driver circuit power supply 106. The controller 102 provides control signals (e.g., commands) to the driver circuit 104 and the driver circuit power supply 106. For example, the controller 102 may transmit a command signal to the driver circuit power supply 106 indicating an amount of power to provide to the driver circuit 104. The controller 102 may also transmit a command signal to the driver circuit 104, such as a pulse width modulated (PWM) signal, that sets a frequency of the driver circuit 104. In some instances, the controller 102 is connected to another controller or device (such as an external controller) via a communication bus 118. In instances where the corona generator 100 is implemented in a vehicle, the controller 102 may be connected to a vehicle electronic control unit (ECU) via the communication bus 118.

The driver circuit power supply 106 receives command signals from the controller 102 indicating an amount of power to provide to the driver circuit 104. The driver circuit power supply 106 provides the indicated amount of power to the driver circuit 104.

The driver circuit 104 receives command signals from the controller 102 that set a frequency of the driver circuit 104 and receives power from the driver circuit power supply 106. The driver circuit 104 operates as a driver for the resonant converter 108 and provides a driver signal having a voltage magnitude and a frequency to the resonant converter 108.

The resonant converter 108 may be, for example, a transformer that receives the driver signal from the resonant converter 108. In some implementations the resonant converter 108 has, for example, a primary inductance (1V at 10 kHz) of approximately 80 μH, a leakage inductance (1V at 10 kHz) of approximately 8 μH, and a primary parallel winding capacitance of 84.4 nF. The resonant converter 108 may have a primary DC resistance value of approximately 350 mΩ and a secondary DC resistance value of approximately 240Ω. In some instances, the resonant converter 108 has a primary-to-secondary turns ratio of approximately 1:138. The resonant converter 108 may have a high potential (Hi-Pot) value of approximately 3.5 kVDC. These values are merely examples, and transformers having other operational characteristics may also be implemented as the resonant converter 108.

The voltage multiplier 110 amplifies (e.g., boosts) an output of the resonant converter 108. The voltage multiplier 110 outputs a high voltage corona generator output Vₒᵤₜ. The high voltage corona generator output Vₒᵤₜ may have a voltage within the range of, for example, −7 kV to −11 kV. In some applications, such as when the corona generator 100 is used for ozone generation, the high voltage corona generator output Vₒᵤₜ may have a voltage of up to −20 kV. The corona generator output Vₒᵤₜ may create, for example, a corona discharge for ozone generation and/or for air purification.

In some instances, the corona generator 100 also includes feedback circuitry, such as an output voltage feedback circuit 112, a current feedback circuit 114, and a power supply feedback circuit 116. The output voltage feedback circuit 112 is connected between the controller 102 and the corona generator output Vₒᵤₜ and indicates the voltage of the corona generator output Vₒᵤₜ to the controller 102. The current feedback circuit 114 is connected between the controller 102 and the corona generator output Vₒᵤₜ and indicates the current of the corona generator output Vₒᵤₜ. In the illustrated example of FIG. 1, the current feedback circuit 114 is connected between a first resistor R1 and a second resistor R2. The power supply feedback circuit 116 is connected between the driver circuit power supply 106 and the controller 102 and indicates to the controller 102 the power output by the driver circuit power supply 106.

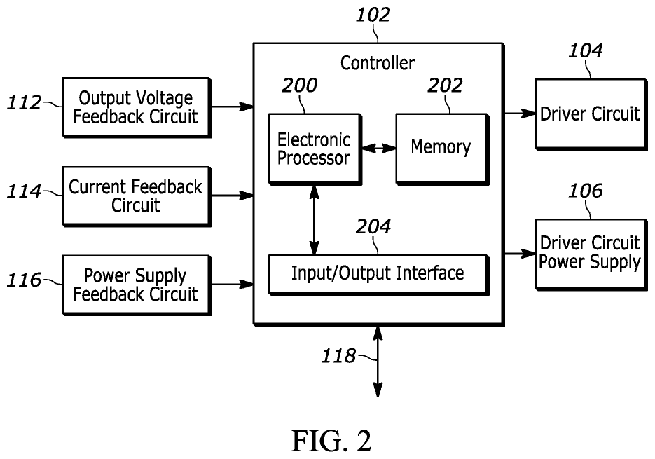

FIG. 2 illustrates a block diagram of the controller 102 of FIG. 1 in accordance with some aspects. The controller 102 includes, among other things, an electronic processor 200, a memory 202, and an input/output (I/O) interface 204. The electronic processor 200, the memory 202, and the I/O interface 204 communicate over one or more control and/or data buses. FIG. 2 illustrates only one example of the controller 102. The controller 102 may include more or fewer components and may perform functions other than those explicitly described herein.

In some examples, the electronic processor 200 is implemented as a microcontroller with a separate memory, such as the memory 202. In other examples, the electronic processor 200 may be implemented as a microcontroller with memory 202 on the same chip. In other examples, the electronic processor 200 may be implemented partially or entirely as, for example, a field-programmable gate array (FPGA), an applications specific integrated circuit (ASIC), and the like and the memory 202 may not be needed or may be modified accordingly. In the example illustrated, the memory 202 includes non-transitory, computer-readable memory (or medium) that stores instructions that are received and executed by the electronic processor 200 to carry out the functionality of the corona generator 100 described herein. The memory 202 may include, for example, a program storage area and a data storage area. The program storage area and the data storage area may include combinations of different types of memory, such as non-volatile read-only memory, non-volatile flash memory and volatile random-access memory.

The I/O interface 204 may include one or more input mechanisms (for example, a touch pad, a keyboard, and the like), one or more output mechanisms (for example, a display, a speaker, and the like), or a combination thereof, or a combined input and output mechanism such as a touch screen. The I/O interface 204 may include a transceiver that enables wired and/or wireless communication of the controller 102 with another device. For example, the I/O interface 204 may enable communication of the controller 102 with another device such as the Electronic Control Unit (ECU) in a vehicle connected via the communication bus 118.

The controller 102 receives feedback regarding the state of the corona generator 100 from the output voltage feedback circuit 112, the current feedback circuit 114, and the power supply feedback circuit 116. For example, the output voltage feedback circuit 112 provides a signal to the controller 102 indicative of an output voltage of the corona generator 100. The current feedback circuit 114 provides a signal to the controller 102 indicative of an output current of the corona generator 100. The power supply feedback circuit 116 provides a signal to the controller 102 indicative of a power (e.g., a voltage and/or a current) provided by the driver circuit power supply 106 to the driver circuit 104. The controller 102 processes (for example, analyzes) these feedback signals and determines what commands to provide to the driver circuit 104 and the driver circuit power supply 106 based on the feedback signals. For example, based on the feedback signals, the controller 102 determines a voltage that the driver circuit power supply 106 should provide to the driver circuit 104, and transmits a command to the driver circuit power supply 106 indicating that voltage. In another example, based on the feedback signals, the controller 102 determines a frequency at which to drive the driver circuit 104, and transmits a command to the driver circuit 104 to drive the driver circuit 104 at the determined frequency. Further operation of the controller 102 is described in more detail below.

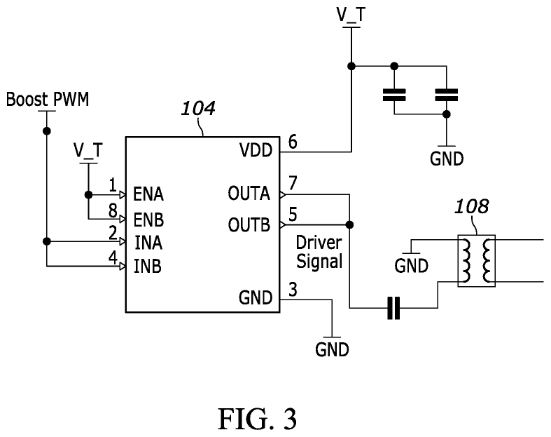

FIG. 3 illustrates a circuit diagram of the driver circuit 104 in accordance with some aspects. In the illustrated example of FIG. 3, the driver circuit 104 is a dual output low side MOSFET/IGBT gate driver. The driver circuit 104 of the illustrated example includes two operating channels. The first operating channel has input terminals Enable A (ENA) and Input A (INA) and output terminal Output A (OUTA). The second operating channel has input terminals Enable B (ENB) and Input B (INB) and output terminal Output B (OUTB). However, other types of driver circuits may be implemented. The driver circuit 104 receives a supply voltage V_T which has a voltage range of between approximately 4.5V to 18V. In some instances, the supply voltage V_T has a voltage of approximately 12V, such as when a vehicle battery provides power to the corona generator 100. The supply voltage V_T may be provided by the driver circuit power supply 106 (via terminals ENA, ENB, and VDD). In instances where the driver circuit 104 is a gate driver, the driver circuit 104 may both source and sink current. In such instances, the ENA and ENB inputs may be connected in parallel, the INA and INB inputs may be connected in parallel, and the OUTA and OUTB outputs may be connected in parallel, such that the channels of the driver circuit 104 are connected in parallel, thereby providing higher current source and sink capability.

The driver circuit 104 also receives the command signal BOOST_PWM from the controller 102 as an input (to terminals INA and INB). The command signal may be, for example, a PWM signal having a frequency set by the controller 102. In some implementations, the driver signal is a logic level square wave. The output of the driver circuit 104 (at terminals OUTA and OUTB) is a driver signal having a magnitude approximately equal to the supply voltage V_T from the driver circuit power supply 106 and having a frequency and/or shape approximately equal to the command signal BOOST_PWM. For example, when the command signal is a square wave, the driver signal output by the driver circuit 104 to the resonant converter 108 is a square wave of magnitude V_T. In other implementations, the driver signal may be a sinusoidal wave.

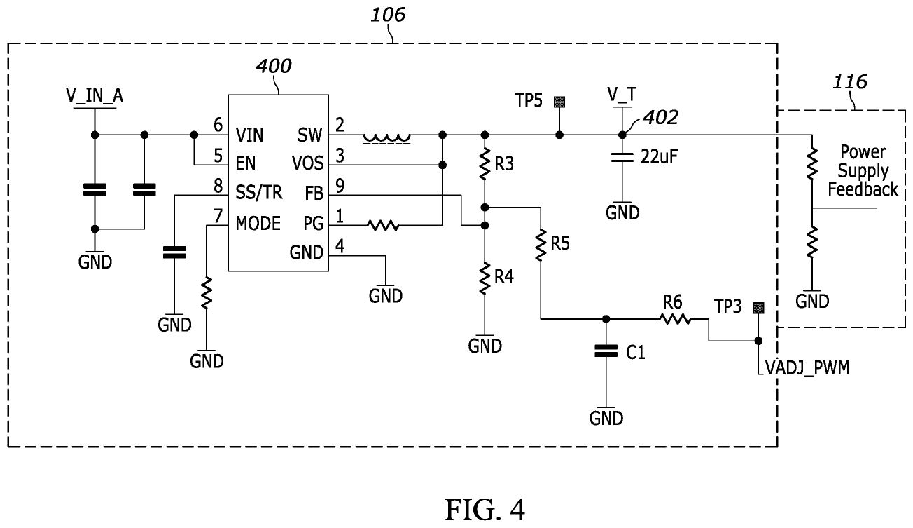

FIG. 4 illustrates a circuit diagram of the driver circuit power supply 106 in accordance with some aspects. The circuit diagram of FIG. 4 also illustrates an example power supply feedback circuit 116. As the magnitude of the driver signal output by the driver circuit 104 is approximately equal to the power supplied by the driver circuit power supply 106 to the driver circuit 104, dynamically adjusting the power supplied by the driver circuit power supply 106 adjusts the power applied to the resonant converter 108.

In the example illustrated in FIG. 4, the driver circuit power supply 106 includes a buck regulator 400. However, other topologies may alternatively be implemented, such as a boost regulator or a buck-boost regulator. The buck regulator 400 receives input power V_IN_A, which is the power supply to the corona generator 100 (for example, power supplied by a vehicle battery). The buck regulator 400 outputs a reduced voltage which is less than the input voltage V_IN_A. The output voltage V_T of the driver circuit power supply 106 (shown at node 402) is fixed according to the values of R3, R4, R5, and low-pass filter C1/R6.

The driver circuit power supply 106 receives command signal VADJ_PWM from the controller 102 that indicates a desired output power from the driver circuit power supply 106. The command signal VADJ_PWM may be a PWM signal having a duty cycle that is supplied directly from the controller 102. The command signal VADJ_PWM is rectified by the low pass filter C1/R6, effectively providing a DC signal to R5 and negating the need for a dedicated digital-analog converter. When the controller 102 adjusts the duty cycle of the command signal VADJ_PWM, the output voltage V_T of the driver circuit power supply 106 changes. In this manner, by adjusting the duty cycle of the command signal VADJ_PWM, the controller 102 controls the output voltage V_T of the driver circuit power supply 106 that is provided to the driver circuit 104. Table 1, shown below, provides example values of V_T and Vₒᵤₜ for different duty cycle values of VADJ_PWM. In the example of Table 1, R1=270 KΩ, R2=24.5 kΩ, R3=270 KΩ, and the switching frequency is 55 kHz. Ranges of achievable minimum and maximum voltages is dependent on the values of R1, R2, and R3.

TABLE 1
Driver Circuit Voltages Based On Duty Cycle

| VADJ_PWM | Driver Circuit Voltage | Generator Output Voltage |
|---|---|---|
| Duty Cycle | V_T (V) | Vₒᵤₜ (kV) |
| 1% | 7.85 | −9.81 |
| 25% | 7.42 | −9.26 |
| 50% | 6.98 | −8.92 |
| 75% | 6.54 | −8.55 |
| 99% | 6.1 | −8.16 |

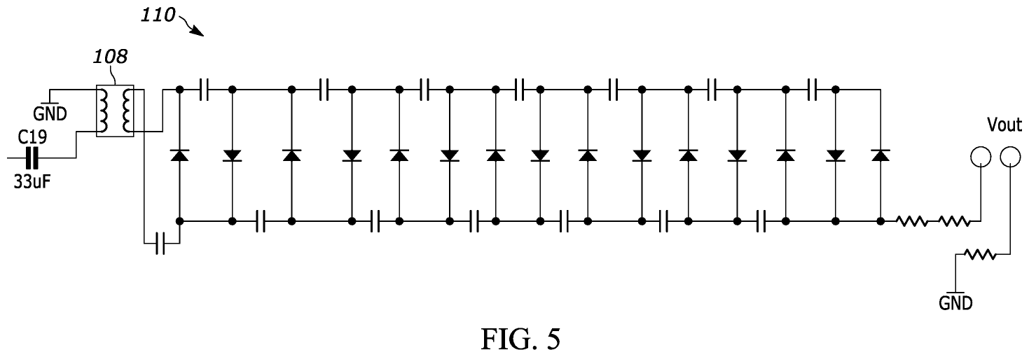

FIG. 5 illustrates a circuit diagram of the voltage multiplier 110 in accordance with some aspects. The voltage multiplier 110 is connected to an output terminal of the resonant converter 108 and amplifies the output of the resonant converter 108 to generate the output voltage Vₒᵤₜ of the corona generator 100. In the example of FIG. 5, the voltage multiplier 110 is a 7-stage Villard voltage multiplier. However, other types of voltage multiplier circuits may alternatively be implemented.

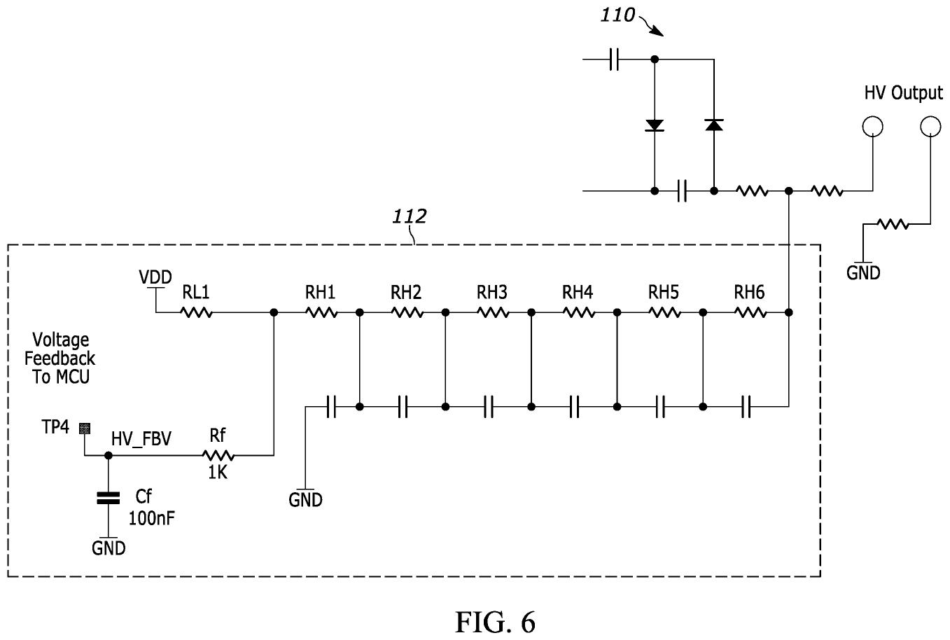

FIG. 6 illustrates a circuit diagram of the output voltage feedback circuit 112 in accordance with some aspects. The output voltage feedback circuit 112 is connected to the output of the voltage multiplier 110 and senses the output voltage Vₒᵤₜ of the corona generator 100. The output voltage feedback circuit 112 conditions the output voltage Vₒᵤₜ (for example, reduces the magnitude of the output voltage Vₒᵤₜ) to a voltage feedback signal that can be processed by the controller 102. The voltage feedback signal is provided by the output voltage feedback circuit 112 to the controller 102. With reference to FIG. 6, the output voltage Vₒᵤₜ may be inferred from voltage feedback signal HV_FBV according to the formula Vₒᵤₜ=HV_FBV−(RH1+RH2+RH3+RH4+RH5+RH6)*(VDD−HV_FBV)/RL1. For example, if the sum of RH1-RH6 is 600 MΩ and RL1 is 120 kΩ and VDD=3.3V, a feedback voltage HV_FBV=0.75V would imply an output voltage Vₒᵤₜ=−12.8 kV.

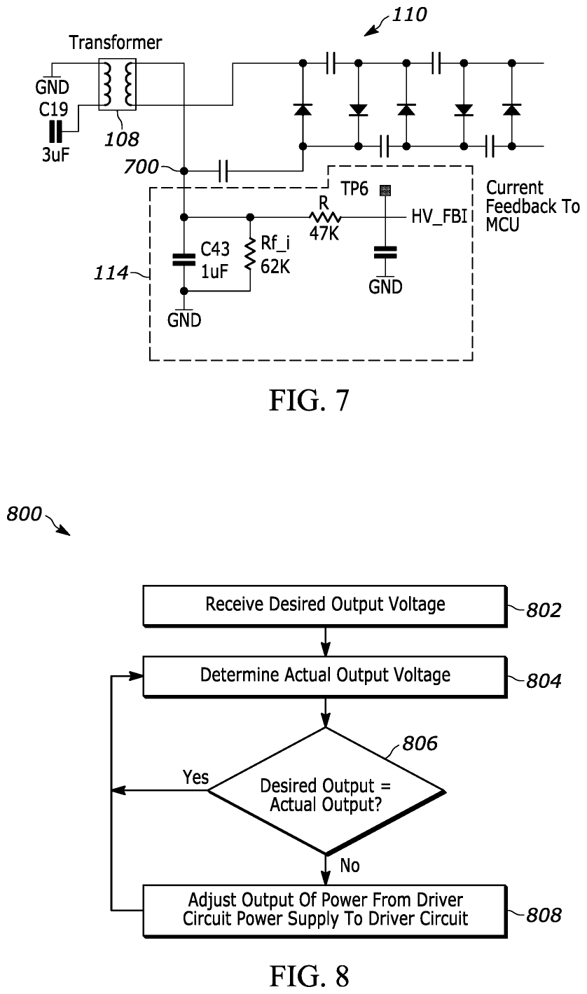

FIG. 7 illustrates a circuit diagram of the current feedback circuit 114 in accordance with some aspects. The current feedback circuit 114 is connected in parallel with the resonant converter 108 and the voltage multiplier 110. Specifically, the current feedback circuit 114 is connected at a node 700 at an output of the resonant converter 108 and an input of the voltage multiplier 110. The current in the secondary side of the circuit can be inferred from the voltage HV_FBI according to the resistor Rf_i (in the example of FIG. 7, a 62K resistor), that is current=HV_FBI/62000 Amperes. For example, if the feedback voltage was 2V, a current of 32.26 μA can be inferred. Since the magnitude of HV_FBI may not be greater than VDD, the value of the 62K resistor can be changed to suit the maximum expected current Iₘₐₓ. For a particular application, Rf_i<VDD/(Iₘₐₓ).

As previously mentioned, the controller 102 processes feedback signals from the output voltage feedback circuit 112, the current feedback circuit 114 and the power supply feedback circuit 116 when controlling the driver circuit 104 and the driver circuit power supply 106. As one example, FIG. 8 illustrates a block diagram of a method 800 for adjusting power provided to the driver circuit 104. The method 800 is described as being executed by the controller 102. However, in some examples, aspects of the method 800 may be performed by another processing device. For example, the method 800 may be performed by the controller 102 in conjunction with another processing device connected via the communication bus 118.

At block 802, the controller 102 receives a desired output voltage of the corona generator 100. The desired output voltage may be received from, for example, a vehicle controller of a vehicle connected to the controller 102 via the communication bus 118. In some instances, the desired output voltage is a range of acceptable output voltages.

At block 804, the controller 102 determines an actual output voltage of the corona generator 100. For example, the controller 102 receives a voltage feedback signal from the output voltage feedback circuit 112 indicative of the output voltage Vₒᵤₜ of the corona generator 100.

At block 806, the controller 102 determines whether the desired output voltage of the corona generator 100 is equal to (or approximately equal to) the actual output voltage Vₒᵤₜ of the corona generator 100. In some examples, the controller 102 determines whether the actual output voltage Vₒᵤₜ of the corona generator 100 is within the range of acceptable output voltages. The range of acceptable output voltages for the corona generator 100 may be, for example, within −15% and +15% of the desired output voltage.

When the desired output voltage of the corona generator 100 is approximately equal to the actual output voltage Vₒᵤₜ of the corona generator 100, the controller 102, in response, returns to block 804 and continues to monitor the output voltage of the corona generator 100. When the desired output voltage of the corona generator 100 is not equal to the actual output voltage Vₒᵤₜ of the corona generator 100, the controller 102, in response, proceeds to block 808. At block 808, the controller 102 adjusts the output of power from the driver circuit power supply 106 to the driver circuit 104. For example, when the actual output voltage Vₒᵤₜ is less than the desired output voltage, the controller 102 may transmit a command to the driver circuit power supply 106 to increase the amount of power provided to the driver circuit 104. When the actual output voltage is greater than the desired output voltage, the controller 102 may transmit a command to the driver circuit power supply 106 to decrease the amount of power provided to the driver circuit 104.

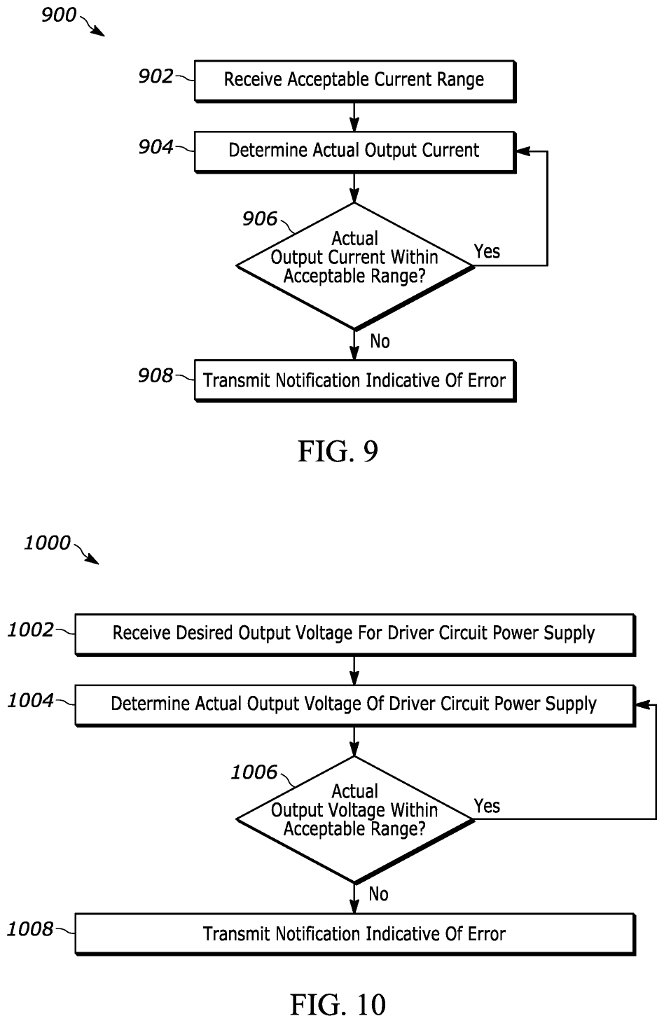

In some instances, the controller 102 detects operational errors of the corona generator 100 based on feedback signals from the output voltage feedback circuit 112, the current feedback circuit 114, and/or the power supply feedback circuit 116. As one example, FIG. 9 illustrates a block diagram of a method 900 for detecting an operational error of the corona generator 100. The method 900 is described as being executed by the controller 102. However, in some examples, aspects of the method 900 may be performed by another processing device. For example, the method 900 may be performed by the controller 102 in conjunction with another processing device connected via the communication bus 118.

At block 902, the controller 102 receives a range of acceptable current values of the corona generator 100. The range of acceptable current values may be received from, for example, a vehicle controller of a vehicle connected to the controller 102 via the communication bus 118. In some instances, the range of acceptable current values is pre-loaded and stored in the memory 202. The electronic processor 200 may then access (e.g., request) the range of acceptable current values from the memory 202.

At block 904, the controller 102 determines an actual output current of the corona generator 100. For example, the controller 102 receives a current feedback signal from the current feedback circuit 114 indicative of the output current of the corona generator 100.

At block 906, the controller 102 determines whether the actual output current of the corona generator 100 is within the range of acceptable current values for the corona generator 100. When the output current of the corona generator 100 is within the range of acceptable current values, the controller 102, in response, returns to block 904 and continues to monitor the output current of the corona generator 100. When the output current of the corona generator 100 is not within the range of acceptable current values, the controller 102, in response, proceeds to block 908.

At block 908, the controller 102 transmits a notification indicative of a detected error of the corona generator 100. For example, the controller 102 transmits a notification to the vehicle controller connected to the controller 102 via the communication bus 118 indicating the error.

FIG. 10 illustrates a block diagram of another method 1000 for detecting an operational error of the corona generator 100. The method 1000 is described as being executed by the controller 102. However, in some examples, aspects of the method 1000 may be performed by another processing device. For example, the method 1000 may be performed by the controller 102 in conjunction with another processing device connected via the communication bus 118.

At block 1002, the controller 102 receives a desired output voltage for the driver circuit power supply 106 to provide to the driver circuit 104. The desired output voltage for the driver circuit power supply 106 may be received from, for example, a vehicle controller of a vehicle connected to the controller 102 via the communication bus 118. In some instances, the desired output voltage for the driver circuit power supply 106 is pre-loaded and stored in the memory 202. The electronic processor 200 may then access (e.g., request) the desired output voltage from the memory 202.

At block 1004, the controller 102 determines the actual output voltage of the driver circuit power supply 106 to the driver circuit 104. For example, the controller 102 receives a power supply feedback signal from the power supply feedback circuit 116 indicative of the voltage provided by the driver circuit power supply 106 to the driver circuit 104.

At block 1006, the controller 102 determines whether the actual output voltage of the driver circuit power supply 106 is within an acceptable range of the desired output voltage. When the actual output voltage of the driver circuit power supply 106 is within the acceptable range of the desired output voltage, the controller 102 returns to block 1004 and continues to monitor the output voltage of the driver circuit power supply 106. When the actual output voltage of the driver circuit power supply 106 is not within the acceptable range of the desired output voltage, the controller 102 proceed to block 1008.

At block 1008, the controller 102 transmits a notification indicative of a detected error of the corona generator 100. For example, the controller 102 transmits a notification to the vehicle controller connected to the controller 102 via the communication bus 118 indicating the error.

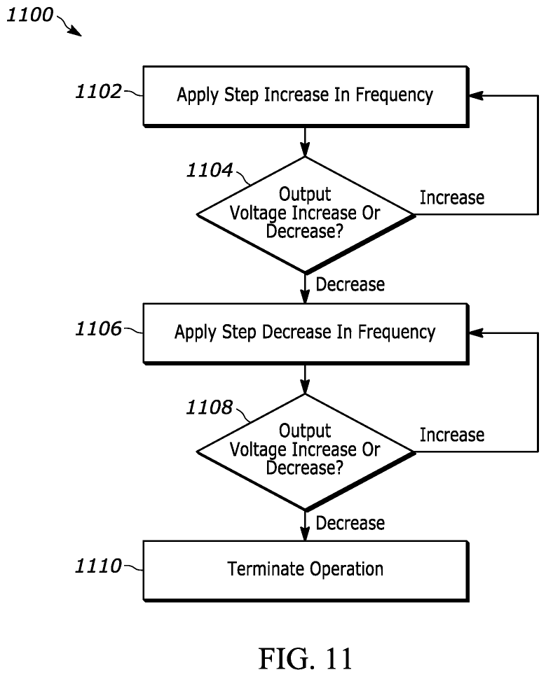

While a range of frequencies are possible for operating the resonant converter 108, in some instances, an optimal frequency for operation of the resonant converter 108 may exist. Accordingly, a control loop may be performed by the controller 102 to tune and adjust the operating frequency of the resonant converter 108 based on changing conditions. For example, changes in temperature and/or moisture may change the optimal frequency of the resonant converter 108. FIG. 11 illustrates a block diagram of another method 1100 for adjusting an operating frequency of the driver circuit 104. The method 1100 is described as being executed by the controller 102. However, in some examples, aspects of the method 1100 may be performed by another processing device. For example, the method 1100 may be performed by the controller 102 in conjunction with another processing device connected via the communication bus 118.

At block 1102, the controller 102 applies a step increase in the operating frequency of the driver circuit 104. For example, the controller 102 increases the frequency of the command signal BOOST_PWM provided to the driver circuit 104. In some instances, the step increase in the operating frequency is less than 1%.

At block 1104, the controller 102 determines whether the output voltage of the corona generator 100 increases or decreases based on the step increase in the operating frequency of the driver circuit 104. For example, the controller 102 receives an output voltage feedback signal from the output voltage feedback circuit 112. When the operating frequency of the driver circuit 104 increases, a response occurs in the output voltage of the corona generator 100. The controller 102 processes the output voltage feedback signal and determines whether the output voltage of the corona generator 100 has increased or decreased (for example, by comparing the new output voltage to a previous output voltage). When the output voltage of the corona generator 100 increases, the controller 102 returns to block 1102 and applies an additional step increase in the operating frequency of the driver circuit 104. In this manner, as long as increases in the frequency results in an increase of the output voltage of the corona generator 100 at block 1104, the controller 102 continues to increase the frequency at block 1102.

When the output voltage of the corona generator 100 decreases in response to the increase in operating frequency of the driver circuit 104, the controller 102 proceeds to block 1106. At block 1106, the controller 102 applies a step decrease in the operating frequency of the driver circuit 104. For example, the controller 102 decreases the frequency of the command signal BOOST_PWM provided to the driver circuit 104.

At block 1108, the controller 102 determines whether the output voltage of the corona generator 100 increases or decreases based on the step decrease in the operating frequency of the driver circuit 104. For example, the controller 102 receives an output voltage feedback signal from the output voltage feedback circuit 112. The controller 102 processes the output voltage feedback signal and determines whether the output voltage of the corona generator 100 has increased or decreased (for example, by comparing the new output voltage to a previous output voltage). When the output voltage of the corona generator 100 increases, the controller 102 returns to block 1106 and applies an additional step decrease in the operating frequency of the driver circuit 104. In this manner, as long as increases in the frequency results in an increase of the output voltage of the corona generator 100 at block 1108, the controller 102 continues to decrease the frequency at block 1106.

When the output voltage of the corona generator 100 decreases in response to the decrease in operating frequency of the driver circuit 104, the controller 102 proceeds to block 1110. At block 1110, the controller 102 terminates the looping operation. In such an instance, the resonant converter 108 is assumed to be operating at the optimal frequency. In some embodiments, the controller 102 periodically performs the method 1100 (for example, once every minute, once every hour, etc.) to account for variations in environmental conditions of the resonant converter 108.

Examples, aspects, and instances described herein provide particular advantages over traditional corona generators. For example, the circuitry and topologies described herein are simple to implement and require few components compared to traditional corona generators, enabling implementations in air cleaners or ozone generators in automotive applications. For example, by using a transformer as the resonant converter, parasitic elements of the transformer are utilized as part of the resonant tank, eliminating the need for additional capacitors. Additionally, components typically needed for Fly-Forward topologies, such as diodes, capacitors, and resistors in resistor-capacitor-diode (RCD) snubbers, are not needed for topologies described herein, saving on cost and space.

The closed-loop controls of the resonant converter described herein also provide additional advantages over traditional corona generators. Methods described herein maintain the desired output voltage of the corona generator while accounting for variations in environmental conditions of the resonant converter. For example, for air purification applications the quality of air that is being cleaned and its makeup, as well as the amount of moisture present, is accounted for during control of the resonant converter. Additionally, desired outputs of the corona generator may be altered without any changes in hardware or firmware.

Various instances and aspects of the inventions described herein are summarized by the following clauses:

Clause 1: A corona generator comprising: a resonant converter; a voltage multiplier circuit connected to the resonant converter and configured to amplify a converter output voltage of the resonant converter, thereby generating a corona generator output; a driver circuit connected to the resonant converter and configured to provide a driver signal to the resonant converter; a driver circuit power supply configured to provide power to the driver circuit; and a controller including an electronic processor, the controller connected to the driver circuit and the driver circuit power supply, the controller configured to: receive voltage feedback indicative of a voltage of the corona generator output, compare the voltage feedback to a desired output voltage of the corona generator output, and transmit a command to the driver circuit power supply to adjust an amount of power provided to the driver circuit.

Clause 2: The corona generator of clause 1, wherein the resonant converter is a transformer.

Clause 3: The corona generator of any of clause 1 to 2, wherein the corona generator output creates a corona discharge for ozone generation.

Clause 4: The corona generator of any of clause 1 to 3, wherein the controller is configured to: receive the desired output voltage from an external controller.

Clause 5: The corona generator of any of clause 1 to 4, wherein the driver signal is a square wave having a magnitude approximately equal to the amount of power provided by the driver circuit power supply to the driver circuit.

Clause 6: The corona generator of clause 5, wherein the driver circuit is configured to adjust a duty cycle of the square wave based on the amount of power provided by the driver circuit power supply to the driver circuit.

Clause 7: The corona generator of any of clause 1 to clause 6, wherein the voltage multiplier circuit is a 7-stage Villard voltage multiplier.

Clause 8: The corona generator of any of clause 1 to clause 7, wherein the controller is further configured to: receive current feedback indicative of an output current of the voltage multiplier circuit; determine whether the output current is within an acceptable current range; and provide, in response to the output current not being within the acceptable current range, a notification indicative of an error.

Clause 9: The corona generator of any of clause 1 to clause 8, wherein the controller is further configured to: determine whether the power provided by the driver circuit power supply is within an acceptable voltage range; and provide, in response to the power provided by the driver circuit power supply not being within the acceptable voltage range, a notification indicative of an error.

Clause 10: The corona generator of any of clause 1 to clause 9, further comprising a voltage feedback circuit configured to provide the voltage feedback to the controller, wherein the voltage feedback circuit is connected between the voltage multiplier circuit and the controller, wherein the voltage feedback circuit includes a plurality of parallel circuits, and wherein each parallel circuit includes a resistor connected in parallel with a capacitor.

Clause 11: The corona generator of any of clause 1 to clause 10, further comprising a current feedback circuit configured to provide current feedback to the controller, wherein the current feedback circuit includes a resistor connected between the resonant converter and the voltage multiplier circuit.

Clause 12: The corona generator of any of clause 1 to clause 11, wherein the controller is further configured to: transmit a pulse width modulated (PWM) signal to the driver circuit, the PWM signal having a frequency; and adjust the frequency of the PWM signal based on the voltage feedback.

Clause 13: A method for controlling a corona generator, the corona generator including a resonant converter, a voltage multiplier circuit connected to the resonant converter and configured to amplify a converter output voltage of the resonant converter, thereby generating a corona generator output, a driver circuit connected to the resonant converter and configured to provide a driver signal to the resonant converter, and a driver circuit power supply configured to provide power to the driver circuit, the method comprising: receiving voltage feedback indicative of a voltage of the corona generator output, comparing the voltage feedback to a desired output voltage of the corona generator output, and transmitting a command to the driver circuit power supply to adjust an amount of power provided to the driver circuit.

Clause 14: The method of clause 13, further comprising: receiving the desired output voltage from an external controller of a vehicle.

Clause 15: The method of any of clause 13 to 14, wherein the driver signal is a square wave having a magnitude approximately equal to the amount of power provided by the driver circuit power supply to the driver circuit.

Clause 16: The method of clause 15, further comprising: adjusting, with the driver circuit, a duty cycle of the square wave based on the amount of power provided by the driver circuit power supply to the driver circuit.

Clause 17: The method of any of clause 13 to 16, further comprising: receiving current feedback indicative of an output current of the voltage multiplier circuit; determining whether the output current is within an acceptable current range; and providing, in response to the output current not being within the acceptable current range, a notification indicative of an error.

Clause 18: The method of any of clause 13 to 17, further comprising: determining whether the power provided by the driver circuit power supply is within an acceptable voltage range; and providing, in response to the power provided by the driver circuit power supply not being within the acceptable voltage range, a notification indicative of an error.

Clause 19: The method of any of clause 13 to 18, further comprising: transmitting a pulse width modulated (PWM) signal to the driver circuit, the PWM signal having a frequency; and adjusting the frequency of the PWM signal based on the voltage feedback.

Clause 20: A non-transitory computer-readable medium storing instructions that, when executed by an electronic processor, cause the electronic processor to perform operations comprising the method of any of clause 13 to 19.

In the foregoing specification, specific examples have been described. However, one of ordinary skill in the art appreciates that various modifications and changes may be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

In this document relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus.

It should also be noted that a plurality of hardware and software-based devices, as well as a plurality of different structural components may be utilized in various implementations. Aspects, features, and instances may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one instance, the electronic based aspects of the invention may be implemented in software (for example, stored on non-transitory computer-readable medium) executable by one or more processors. As a consequence, it should be noted that a plurality of hardware and software-based devices, as well as a plurality of different structural components may be utilized to implement the invention. For example, “control units” and “controllers” described in the specification can include one or more electronic processors, one or more memories including a non-transitory computer-readable medium, one or more input/output interfaces, and various connections (for example, a system bus) connecting the components.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

It should also be understood that although certain drawings illustrate hardware and software located within particular devices, these depictions are for illustrative purposes only. In some embodiments, the illustrated components may be combined or divided into separate software, firmware, and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable connections or links.

Thus, in the claims, if an apparatus or system is claimed, for example, as including an electronic processor or other element configured in a certain manner, for example, to make multiple determinations, the claim or claim element should be interpreted as meaning one or more electronic processors (or other element) where any one of the one or more electronic processors (or other element) is configured as claimed, for example, to make some or all the multiple determinations collectively. To reiterate, those electronic processors and processing may be distributed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it may be seen that various features are grouped together in various examples for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

What is claimed is:

1. A corona generator comprising:
a resonant converter;
a voltage multiplier circuit connected to the resonant converter and configured to amplify a converter output voltage of the resonant converter, thereby generating a corona generator output;
a driver circuit connected to the resonant converter and configured to provide a driver signal to the resonant converter;
a driver circuit power supply configured to provide power to the driver circuit; and
a controller including an electronic processor, the controller connected to the driver circuit and the driver circuit power supply, the controller configured to:
receive voltage feedback indicative of a voltage of the corona generator output,
compare the voltage feedback to a desired output voltage of the corona generator output, and
transmit a command to the driver circuit power supply to adjust an amount of power provided to the driver circuit.

2. The corona generator of claim 1, wherein the resonant converter is a transformer.

3. The corona generator of claim 1, wherein the corona generator output creates a corona discharge for ozone generation.

4. The corona generator of claim 1, wherein the controller is configured to:
receive the desired output voltage from an external controller.

5. The corona generator of claim 1, wherein the driver signal is a square wave having a magnitude approximately equal to the amount of power provided by the driver circuit power supply to the driver circuit.

6. The corona generator of claim 5, wherein the driver circuit is configured to adjust a duty cycle of the square wave based on the amount of power provided by the driver circuit power supply to the driver circuit.

7. The corona generator of claim 1, wherein the voltage multiplier circuit is a 7-stage Villard voltage multiplier.

8. The corona generator of claim 1, wherein the controller is further configured to:
receive current feedback indicative of an output current of the voltage multiplier circuit;
determine whether the output current is within an acceptable current range; and
provide, in response to the output current not being within the acceptable current range, a notification indicative of an error.

9. The corona generator of claim 1, wherein the controller is further configured to:
determine whether the power provided by the driver circuit power supply is within an acceptable voltage range; and
provide, in response to the power provided by the driver circuit power supply not being within the acceptable voltage range, a notification indicative of an error.

10. The corona generator of claim 1, further comprising a voltage feedback circuit configured to provide the voltage feedback to the controller, wherein the voltage feedback circuit is connected between the voltage multiplier circuit and the controller, wherein the voltage feedback circuit includes a plurality of parallel circuits, and wherein each parallel circuit includes a resistor connected in parallel with a capacitor.

11. The corona generator of claim 1, further comprising a current feedback circuit configured to provide current feedback to the controller, wherein the current feedback circuit includes a resistor connected between the resonant converter and the voltage multiplier circuit.

12. The corona generator of claim 1, wherein the controller is further configured to:
transmit a pulse width modulated (PWM) signal to the driver circuit, the PWM signal having a frequency; and
adjust the frequency of the PWM signal based on the voltage feedback.

13. A method for controlling a corona generator, the corona generator including a resonant converter, a voltage multiplier circuit connected to the resonant converter and configured to amplify a converter output voltage of the resonant converter, thereby generating a corona generator output, a driver circuit connected to the resonant converter and configured to provide a driver signal to the resonant converter, and a driver circuit power supply configured to provide power to the driver circuit, the method comprising:
receiving voltage feedback indicative of a voltage of the corona generator output,
comparing the voltage feedback to a desired output voltage of the corona generator output, and
transmitting a command to the driver circuit power supply to adjust an amount of power provided to the driver circuit.

14. The method of claim 13, further comprising:
receiving the desired output voltage from an external controller of a vehicle.

15. The method of claim 13, wherein the driver signal is a square wave having a magnitude approximately equal to the amount of power provided by the driver circuit power supply to the driver circuit.

16. The method of claim 15, further comprising:
adjusting, with the driver circuit, a duty cycle of the square wave based on the amount of power provided by the driver circuit power supply to the driver circuit.

17. The method of claim 13, further comprising:
receiving current feedback indicative of an output current of the voltage multiplier circuit;
determining whether the output current is within an acceptable current range; and
providing, in response to the output current not being within the acceptable current range, a notification indicative of an error.

18. The method of claim 13, further comprising:
determining whether the power provided by the driver circuit power supply is within an acceptable voltage range; and
providing, in response to the power provided by the driver circuit power supply not being within the acceptable voltage range, a notification indicative of an error.

19. The method of claim 13, further comprising:
transmitting a pulse width modulated (PWM) signal to the driver circuit, the PWM signal having a frequency; and
adjusting the frequency of the PWM signal based on the voltage feedback.

20. A non-transitory computer-readable medium storing instructions that, when executed by an electronic processor, cause the electronic processor to perform operations comprising the method of claim 13.
